(19) United States
(12) Patent Application Publication
(10) Pub. No.: US 2026/0068102 A1
(43) Pub. Date: Mar. 5, 2026

(54) RACK LEVEL AIR STREAM MIXING FOR ELECTROSTATIC DISCHARGE (ESD) PREVENTION

(71) Applicant: INTERNATIONAL BUSINESS MACHINES CORPORATION, ARMONK, NY (US)

(72) Inventors: Dustin Demetriou, Hyde Park, NY (US); Wolf Wolbeck, Wurtsboro, NY (US); John S. Werner, Fishkill, NY (US); Robert Walsh, Wallkill, NY (US); Arkadiy O. Tsfasman, Wappingers Falls, NY (US)

(21) Appl. No.: 18/820,812

(22) Filed: Aug. 30, 2024

(51) Int. Cl. H05K 7/20

(52) U.S. Cl. CPC H05K 7/20736; H05K 7/20145; H05K 7/20172; H05K 7/20181; H05K 7/20209

(57) ABSTRACT

Decreasing the likelihood of electrostatic discharge (ESD) events by increasing relative humidity (RH) in a localized area within a computer rack is provided. An air stream mixing module receives notification of a pending service action. Physical location of the service action is correlated to one or more controllable blocking features and fans. Sensors measure RH at the service action physical location and the air intake location. Controllable blocking features and fans in air carrying conduits are programmatically set based on calculated difference between desired and measured RH percentages. Cool air is drawn into the front of the server rack and through one or more of the air carrying conduits, whereby the cool air mixing with exhaust air increases RH of the area around the components at the target location of the service action.

### BACKGROUND

This invention relates generally to computer systems, and more particularly to managing electrostatic discharge (ESD).

During service actions on electronic equipment, ESD events can occur. In general, an ESD event is a static discharge of built-up electrical energy that can spark to and damage sensitive electronic equipment. The damage may range from partially degraded performance to catastrophic failure. An ESD event may not only reduce the operating life of the affected device, but may also lead to personnel injury.

It would be advantageous to provide a method for localized rack level air stream mixing, thereby reaching optimal relative humidity (RH) levels in their environments and reducing the likelihood of ESD events from occurring.

### SUMMARY

A method is provided for increasing relative humidity (RH) in a localized area within a computer rack or server. An air stream mixing module receives a notification of an upcoming service action. A physical target location of the service action is correlated to one or more controllable blocking features and one or more fans. One or more sensors measure RH at the physical target location of the service action. A calculation is performed of a percent open of the one or more controllable blocking features and percent of pulse width modulation (PWM) to enable the one or more fans in one or more air carrying conduits, based on a difference between the measured RH and a desired RH. Based on the calculated percents, one or more of the controllable blocking features are opened and one or more fans are enabled. Cool air is drawn into the front of the server rack and through one or more of the air carrying conduits, whereby the cool air mixing with the warmer exhaust air increases RH at the target location of the service action.

Embodiments are further directed to computer systems, servers and computer program products having substantially the same features as the above-described computer-implemented method.

### BRIEF DESCRIPTION OF THE SEVERAL VIEWS OF THE DRAWINGS

Embodiments are further directed to computer systems and computer program products having substantially the same features as the above-described computer-implemented method.

FIG. 1 is an illustration of the operating environment of a networked computer, according to an embodiment of the present invention;

FIG. 2 illustrates a network diagram for the implementation of embodiments of the present invention;

FIG. 3 illustrates an image of a server rack showing embodiments of the present invention; and

FIG. 4 illustrates a flow chart for the operation of a system for rack level air stream mixing for ESD prevention.

### DETAILED DESCRIPTION OF THE INVENTION

During service actions on electronic devices, ESD events can occur. In general, an ESD event is a static discharge of built-up electrical energy that can spark to and damage sensitive electronic devices, referring here particularly to computing equipment. The damage may range from partially degraded performance to catastrophic failure. An ESD event may not only reduce the operating life of the affected device, but may also lead to personnel injury. The probability of an ESD event increases as the RH decreases, hence, the need to raise the RH near the location of the service action.

For example, after experiencing an ESD event an electronic device may develop a latent defect, where it is partially degraded yet continues to perform its intended function. The latent defect may result in the operating life of the electronic device being reduced dramatically. Such failures are usually difficult to detect and costly to repair.

In a catastrophic failure, when an electronic device is exposed to an ESD event it may no longer function. The ESD event may have caused a component to melt, a junction breakdown, or an oxide failure causing permanent damage and/or loss of data. In addition to damaging the electronic device, catastrophic ESD events can lead to the downtime of mission and business critical hardware resulting in financial and/or reputational consequences beyond that of just the damaged hardware.

It would be advantageous to provide a server rack apparatus and method that mixes the air stream surrounding the electronic devices, thereby reaching optimal RH levels, and reducing the likelihood of ESD events.

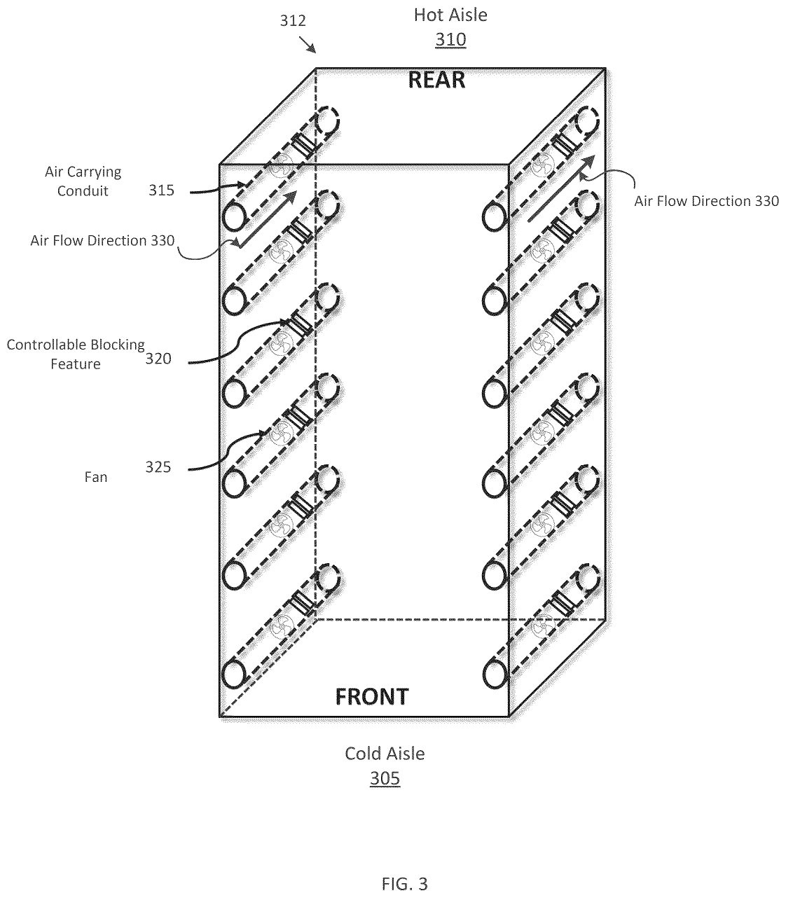

For example, FIG. 3 illustrates an exemplary server rack 312.

In simple hot aisle/cold aisle designs within a computer room or datacenter, server racks 312 are aligned in alternating rows with cold air intakes facing one way (cold aisle 305) and hot air exhausts (hot aisle 310) facing the other. This layout participates in an energy-efficient design to manage airflow in a manner that conserves energy and helps lower cooling costs.

The air carrying conduits 315 (e.g., pipes, tubes, ducts, manifolds, etc.) carry cool air from the front of the server rack 312 to the rear of the server rack 312 and contain one or more blocking features 320 and one or more fans 325. The air flow direction 330 through the air carrying conduits 315 is shown for two air carrying conduits 315 as examples, but the air flow direction 330 is the same (front to back) for each of the air carrying conduits 315 in the server rack 312.

In some embodiments, the outlet of an air carrying conduit 315 may point towards one or more specific locations or one or more specific server components 230 in the rear of server rack 312. In some embodiments, the direction of airflow at the outlet of air carrying conduit 315 is controlled by baffles, louvers, vents, or any component capable of directing air to a desired location. In some embodiments, the air carrying conduits 315 may be integrated into the server rack 312. Alternatively, the air carrying conduits 315 may be a separately purchased feature kit that is installable into the server rack 312, for example, above, below, or on the sides of a specific server component 230.

The controllable blocking features 320 may be louvers, vents, or valves that can be opened or closed via programming instructions from the air stream mixing module 240. The controllable blocking features 320 are optimally only opened in one or more air carrying conduits 315 near a location in which a service action is about to be performed, and all other controllable blocking features 320 in other air carrying conduits 315 are closed such that cool air does not pass to the rear of the server rack 312 in those locations.

The controllable blocking features 320 are programmatically controlled such that they may be deployed fully open, thus allowing air to pass through the server rack 312 through the air carrying conduits 315, or they may be fully closed, thereby not allowing any air to pass through them. However, the percentage open (e.g., 25% open, 50% open, etc.) of the controllable blocking features 120 can be programmatically controlled via programming instructions from the air stream mixing module 240. This allows air flow to be controlled through all air carrying conduits 315, or selectively controlled through one or more air carrying conduits 315 individually and simultaneously. Mixing cool air from the front of the rack with a higher temperature exhaust air increases the RH level in a localized area in the rear of the server rack 312 which reduces the likelihood of an ESD event during a service action. In more humid environments, the moisture in the air provides a path for the static charges to flow and disperse, reducing the likelihood of ESD events. From an electronics manufacturing safety perspective, RH levels above 30% are generally considered better, but for maximum personnel (and component) safety, the humidity levels should be closer to 60%. Conversely, the risk of dangerous electrostatic discharges is highest when humidity levels fall below 30%.

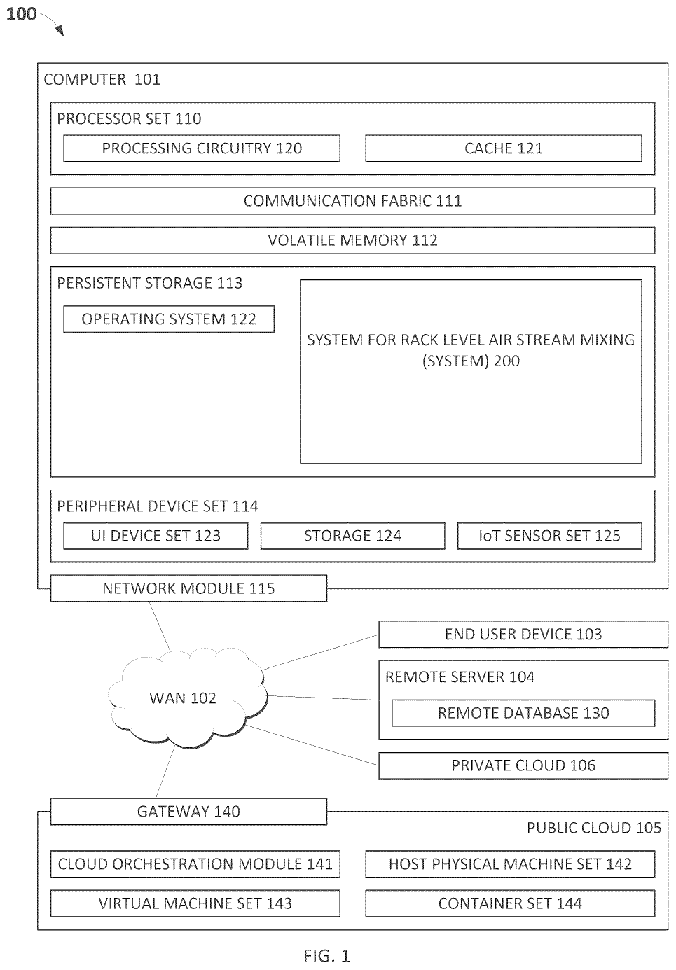

FIG. 1, an illustration is presented of the operating environment of a networked computer, according to an embodiment of the present invention.

Computing environment 100 contains an example of an environment for the execution of at least some of the computer code involved in performing the inventive methods, such as a system for rack level air stream mixing (system) 200, embodied in the application server module 200, air stream mixing module 240, and service action module 245. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, an administrator that operates computer 101), and may take any of the forms discussed above in connection with computer 101. For example, EUD 103 can be the external application by which an end user connects to the control node through WAN 102. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

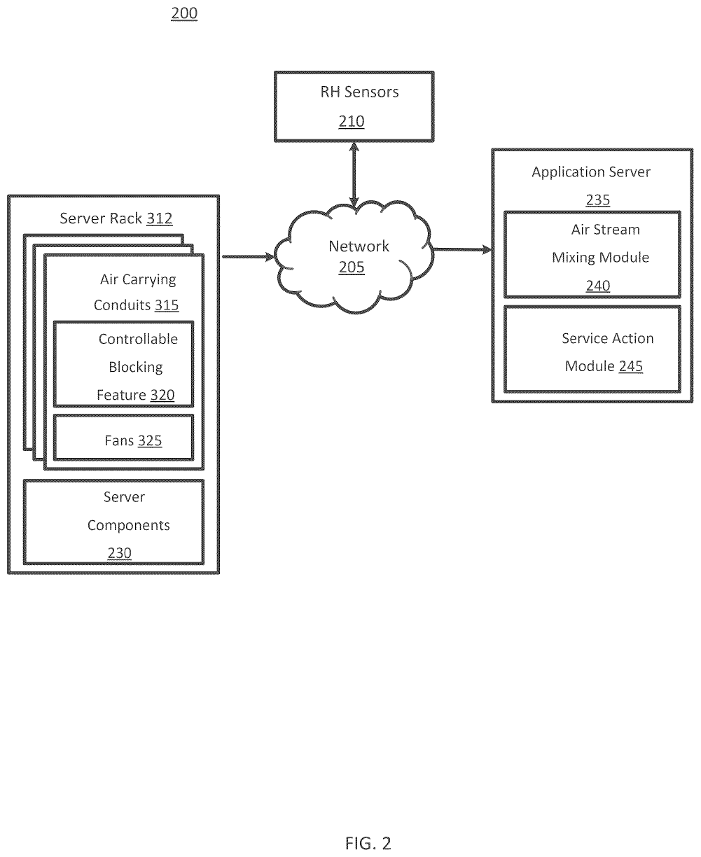

FIG. 2 illustrates a network diagram showing the major components of a server rack level air stream mixing apparatus and the modules required for its control.

The network 205 includes communication to one or more RH sensors 210, deployed within at least one server rack 312 and/or cold aisle 305 or hot aisle 310, and an application server 235, all interconnected via wired and/or wireless network 205.

The wired and/or wireless network 205 may be any communication protocol that allows data to be transferred between components of the system (e.g., Bluetooth, Wi-Fi, Cellular (e.g., 3G, 4G, 5G), Ethernet, fiber optics, etc.).

The RH sensors 210 measure the RH in locations at the rear of server rack 312. In some embodiments, the RH sensors 210 are located within the server rack 312, external to (i.e., behind) server rack 312 (as shown), or can be located within the server components 230. The RH sensors can also be within the one or more air carrying conduits 315.

Server rack 312 is comprised of one or more air carrying conduits 315, as described previously with reference to FIG. 2, and server components 230.

One or more fans 325 are optionally located within one or more air carrying conduits 315 and are used to control the amount of air flow through the server rack 312. Fan speed or PWM is controlled via programming instructions from the air stream mixing module 240, and are disabled when the controllable blocking features 320 are closed.

The server components 230 could be any item installed in the server rack 312 such as a processor drawer, I/O drawer, I/O card, optical transceiver, power supply unit (PSU), ethernet switch, etc. The server components 230 are the components which could experience a failure, require plugging/unplugging of cables, or may require maintenance and are susceptible to an ESD event during those service actions.

The application server 235 component monitors the server rack 312 using the service action module 245 and hosts the air stream mixing module 240. In some embodiments the application server 235 may be located within the server rack 312, for example as a service element (SE). Alternatively, the application server 235 may be external to server rack 312 as shown, for example as integrated into a hardware management console (HMC) or within a data center infrastructure management (DCIM) tool. In some embodiments, the application server 235 may also control other elements for improved air stream mixing to reach a desired RH such as fan speeds of the server components 230, data center cooling unit temperature settings, etc.

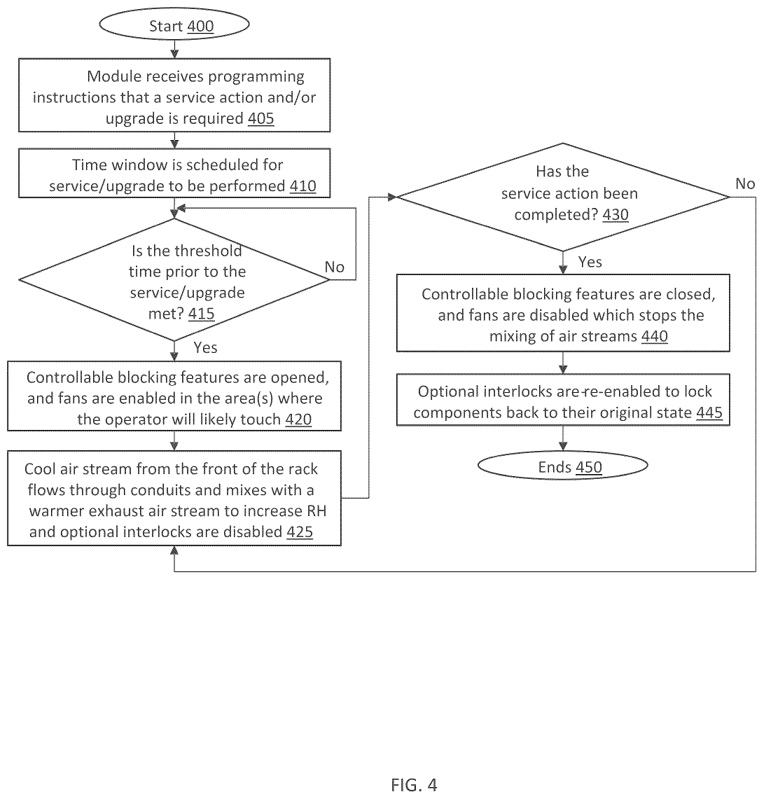

The air stream mixing module 240 operates the controllable blocking features 320 and the fans 325 during a service action to minimize and/or prevent ESD events from occurring. The air stream mixing module 240 is discussed further in FIG. 4.

The service action module 245 detects current or schedules future service actions within server rack 312 and sends programming instructions to the air stream mixing module 240. In some embodiments, service action module 245 monitors the server components 230 to detect faults/errors that require a service action. A service action may additionally include receiving a notification of upgrades or installations of server components 230 that are to be installed within the server rack 312. The service action module 245 may also schedule a preventative maintenance service action for the server components 230, such as receiving a notification prior to plugging/unplugging cables, thereby preventing false errors from being generated.

FIG. 4 illustrates a flow chart for the operation of the air stream mixing module 240 of the system 200.

The air stream mixing module 240 begins at 405 where the server components 230 and/or administrators or programmers send programming instructions to the air stream mixing module 240 that a service action is required. For example, the SE is a specialized computer that runs an operating system and can communicate with an outside computer that may have created a service action. The service action can include a repair or an upgrade to a hardware or software component in the electronic device. The service action can be triggered by a repair and verify (R&V) panel, for example, on the HMC or SE to indicate that the repair is needed as well as the location. The notification of the service action can be a log entry or message with notification of the service to be performed. The notification/message is sent to the air stream mixing module 240, which then receives or creates the time window (date and time range) for this service.

At 410, one of the server components 230 that requires service notifies the air stream mixing module 240, which creates or receives a time window for performing the service action. The time window for a service action can be a specific date and time, or a range of dates/times. The server component 230 receives or creates the service action event, and then activates the air stream mixing module 240 prior to the event. The time window can be passed to the air stream mixing module 240 by a server component 230, or can be created by the air stream mixing module 240 itself.

A threshold amount of time, for example one hour, is embedded into the air stream mixing module 240, and is required to achieve the desired RH levels prior to the service action occurring. The air stream mixing module 240 has this time range built in and when the current time is within the threshold of the service time, (e.g., the one hour before the service will occur) the air stream mixing module 240 activates the fans 325 and controllable blocking features 320 (louvers) as needed. The air stream mixing module 240 either had received the service action event notification from a server component 230, or created it, for example by service personnel through the SE or HMC.

If at 415, the air stream mixing module 240 determines the time window is not within the threshold time period, then the air stream mixing module 240 waits until the threshold time period is reached.

In some embodiments, air stream mixing may begin a threshold amount of time (e.g., 10 minutes, 30 minutes, etc.) prior to the service action starting.

If at 415, the air stream mixing module 240 determines that the time window is within the threshold time period, then at 420, the air stream mixing module 240 instructs one or more of the controllable blocking features 320 to open and enables one or more of the fans 325 in the area(s) where the service personnel will likely touch. This area would be based on the server component 230 being serviced. Otherwise, all controllable blocking features 320 and fans 325 are activated if the air stream mixing module 240 cannot determine this. A percent open of controllable blocking features 320 is set and the fans 325 speeds or PWM are selected based on the current RH sensor 210 readings such that a desired RH can be achieved. The air stream mixing module 240 programmatically uses the RH sensors 210 to measure RH levels. The air stream mixing module 240 activates the controllable blocking features 320 and fans 325 based on the results of the calculation of % RH delta=(desired RH%)−(current RH %).

The relative humidity of the mixed air stream is dependent on the temperature and humidity of each air stream and the percentage of airflow that is mixed from each stream. The fan speed would be controlled to provide the minimum amount of cold air needed to achieve a RH above a threshold, e.g., 30%. This would maximize the efficiency of doing achieving the desired RH. As a result of the operation of the controllable blocking features 320 and the fans 325, a cool air stream continues to flow from the front of the server rack 312 through the air carrying conduits 315 and mixes with a warmer exhaust air stream to increase RH. The air carrying conduits 315 continue to increase the RH until a configurable desired threshold is reached, or the system maximum humidity operating range is reached. The air stream mixing module 240 may continue to programmatically operate the controllable blocking features 320 and the fans 325, as needed, to maintain the desired RH.

In embodiments where optional interlocks are used on doors, bezels, and/or covers, the interlocks can be disabled once a desired RH level is achieved based on readings from one or more RH sensors 210. The optional interlocks are remotely/programmatically operated locks that prevent the service personnel from opening the door to a server rack prior to the desired RH level being reached.

At 430, the air stream mixing module 240 determines whether the service action is complete. This can occur in several ways, depending on the electronic devices involved. For example, in some embodiments, determining if the service action has been completed is achieved based on following steps on the R&V panel. Alternatively, determining if the service action has been completed is achieved based on an update to one of the server components 230 or sensor readings in the system (e.g., proximity sensors, touch sensors, door closing sensor, etc.).

If at 430 the service event is not complete, then the air stream mixing module 240 continues to operate, monitor, and control the RH levels until the service action is complete (425).

However, if at 430 the service event is complete, then the air stream mixing module 240 programmatically instructs the controllable blocking features 320 to close and disables the fans 325. This stops the mixing of air streams.

In embodiments where optional interlocks are used on doors, bezels, and/or covers, the interlocks may be enabled to lock components back to the original state for standard operation at 445 before ending at 450.

As may be used herein, the terms “substantially” and “approximately” provide an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to. ” As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with,” includes direct and/or indirect coupling of separate items and/or one item being embedded within another item.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules, and components herein, can be implemented as illustrated or by discrete components, application specific integrated circuits, processors executing appropriate software and the like or any combination thereof.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from Figure to Figure, the embodiments may incorporate the same or similarly named functions, steps, modules, etc. that may use the same or different reference numbers and, as such, the functions, steps, modules, etc. may be the same or similar functions, steps, modules, etc. or different ones.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information. A computer readable memory/storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for increasing relative humidity (RH) in a localized area within or around a server rack, the method comprising:
receiving, by an air stream mixing module, a notification of a service action;
correlating a physical target location of the service action to one or more controllable blocking features and one or more fans;
measuring, by one or more sensors, a RH at the physical target location of the service action;
calculating a percent open of the one or more controllable blocking features and percent of pulse width modulation (PWM) or speed to enable the one or more fans in one or more air carrying conduits, based on a difference between the measured RH and a desired RH;
based on the calculated percents, opening one or more of the controllable blocking features and enabling the one or more fans; and
drawing cool air into a front of the server rack and through one or more of the air carrying conduits, wherein the cool air mixing with exhaust air increases RH at the target location of the service action.

2. The method of claim 1, wherein the air stream mixing module begins a configurable threshold time prior to the service action being performed, wherein the threshold time is programmatically set in the air stream mixing module, and based on absolute value ((current time)−(service time)) being less than or equal the threshold time.

3. The method of claim 1, wherein the percent open of the one or more controllable blocking features and the percent to enable the one or more fans in the one or more air carrying conduits is programmatically controllable.

4. The method of claim 1, wherein an interlock is locked and prevents access to the physical target location of the service action until reaching a desired RH level, whereupon the interlock is unlocked, and wherein the interlock is re-enabled at the service action end.

5. The method of claim 4, wherein the interlock includes: doors of the server rack, bezels on server components, and covers on server components.

6. The method of claim 1, wherein the sensors measure RH at a rear of the server rack.

7. The method of claim 1, wherein the sensors locations include: within the server rack, external to the server rack, and within one or more server components.

8. A computer program product for increasing relative humidity (RH) in a localized area within a server rack, the computer program product comprising a non-transitory tangible storage device having program code embodied therewith, the program code executable by a processor of a computer to perform a method, the method comprising:
receiving, by an air stream mixing module, a notification of a service action;
correlating a physical target location of the service action to one or more controllable blocking features and one or more fans;
measuring, by one or more sensors, a RH at the physical target location of the service action;
calculating a percent open of the one or more controllable blocking features and percent to enable the one or more fans in one or more air carrying conduits, based on a difference between the measured RH and a desired RH;
based on the calculated percents, opening one or more of the controllable blocking features and enabling the one or more fans; and
drawing cool air into a front of the server rack and through one or more of the air carrying conduits, wherein the cool air mixing with exhaust air increases RH at the target location of the service action.

9. The computer program product of claim 8, wherein the air stream mixing module begins a configurable threshold time prior to the service action being performed.

10. The computer program product of claim 8, wherein the percent open of the one or more controllable blocking features and the percent to enable the one or more fans in the one or more air carrying conduits is programmatically controllable.

11. The computer program product of claim 8, wherein an interlock is locked and prevents access to the physical target location of the service action until reaching a desired RH level, whereupon the interlock is unlocked, and wherein the interlock is re-enabled at the service action end.

12. The computer program product of claim 8, wherein the interlock includes: doors of the server rack, bezels on server components, and covers on server components.

13. The computer program product of claim 8, wherein the sensors measure RH at a rear of the server rack, and wherein the sensors'locations include: within the server rack, external to the server rack, and within one or more server components.

14. A computer system for increasing relative humidity (RH) in a localized area within a computer rack, the computer system comprising:
one or more processors;
a memory coupled to at least one of the processors;
a set of computer program instructions stored in the memory and executed by at least one of the processors in order to perform actions of:
receiving, by an air stream mixing module, a notification of a service action;
correlating a physical target location of the service action to one or more controllable blocking features and one or more fans;
measuring, by one or more sensors, a RH at the physical target location of the service action;
calculating a percent open of the one or more controllable blocking features and percent to enable the one or more fans in one or more air carrying conduits, based on a difference between the measured RH and a desired RH;
based on the calculated percents, opening one or more of the controllable blocking features and enabling the one or more fans; and
drawing cool air into a front of the server rack and through one or more of the air carrying conduits, wherein the cool air mixing with exhaust air increases RH at the target location of the service action.

15. The computer system of claim 14, wherein the air stream mixing module begins a configurable threshold time prior to the service action being performed, wherein the threshold time is programmatically set in the air stream mixing module, and based on absolute value ((current time) - (service time)) being less than or equal the threshold time.

16. The computer system of claim 14, wherein the percent open of the one or more controllable blocking features and the percent to enable the one or more fans in the one or more air carrying conduits is programmatically controllable.

17. The computer system of claim 14, wherein an interlock is locked and prevents access to the physical target location of the service action until reaching a desired RH level, whereupon the interlock is unlocked, and wherein the interlock is re-enabled at the service action end.

18. The computer system of claim 14, wherein the interlock includes: doors of the server rack, bezels on server components, and covers on server components.

19. The computer system of claim 14, wherein the sensors measure RH at a rear of the server rack.

20. The computer system of claim 14, wherein the sensors locations include: within the server rack, external to the server rack, and within one or more server components.
